(19) United States
(12) Patent Application Publication
(10) Pub. No.: US 2024/0405022 A1
(43) Pub. Date: Dec. 5, 2024

(54) NON-PLANAR TRANSISTOR STRUCTURES AND METHODS OF MANUFACTURING THEREOF

(71) Applicant: Tokyo Electron Limited, Tokyo (JP)

(72) Inventors: Eric Chih-Fang LIU, Albany, NY (US); Subhadeep KAL, Albany, NY (US); Peter WANG, Albany, NY (US); Ying TRICKETT, Albany, NY (US); Ya-Ming CHEN, Austin, TX (US)

(73) Assignee: Tokyo Electron Limited, Tokyo (JP)

(21) Appl. No.: 18/204,081

(22) Filed: May 31, 2023

(51) Int. Cl. H01L 27/092; H01L 21/02; H01L 21/8238; H01L 29/10; H01L 29/161

(52) U.S. Cl. CPC H01L 27/0924; H01L 21/02532; H01L 21/823807; H01L 21/823821; H01L 29/1037; H01L 29/161

(57) ABSTRACT

A method for fabricating semiconductor devices is disclosed. The method includes forming a first fin structure and a second fin structure in a first region and a second region of a substrate, respectively, wherein the first and second fin structure and the substrate comprise a first semiconductor material; forming a first liner structure and a second liner structure at least extending along sidewalls of the first fin structure and sidewalls of the second fin structure, respectively; replacing an upper portion of the second fin structure with a second semiconductor material, while leaving the first fin structure substantially intact; and exposing a top surface and upper sidewalls of the first fin structure, and a top surface and upper sidewalls of the second fin structure.

### FIELD OF THE DISCLOSURE

This disclosure relates to microelectronic devices including semiconductor devices, transistors, and integrated circuits, including methods of microfabrication.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### SUMMARY

One aspect of the present disclosure is directed to a semiconductor device. The semiconductor device includes a substrate comprising a first region and a second region; a first fin structure disposed in the first region and comprising a first semiconductor material; and a second fin structure disposed in the second region and comprising a second semiconductor material different from the first semiconductor material. The first fin structure has a first height and the second fin structure has a second height, the second height being greater than the first height.

In some embodiments, the first fin structure protrudes from a major surface of the substrate and comprises only the first semiconductor material. The second fin structure protrudes from the major surface of the substrate and comprises both the first semiconductor material and the second semiconductor material. The second fin structure has a lower portion formed of the first semiconductor material, and an upper portion formed of the second semiconductor material.

In some embodiments, the semiconductor device includes a first liner structure extending sidewalls of a lower portion of the first fin structure; and a second liner structure extending sidewalls of a lower portion of the second fin structure. An interface between an upper portion and the lower portion of the second fin structure is vertically located slightly below a top surface of the second liner structure. The lower portion is formed of the first semiconductor material, while the upper portion is formed of the second semiconductor material.

In some embodiments, the first fin structure operatively serves as a conduction channel of an n-type field-effect-transistor, and the second fin structure operatively serves as a conduction channel of a p-type field-effect-transistor.

In some embodiments, the first semiconductor material is silicon, and the second semiconductor material is silicon germanium.

Another aspect of the present disclosure is directed to a method for fabricating semiconductor devices. The method includes forming a first fin structure and a second fin structure in a first region and a second region of a substrate, respectively, wherein the first and second fin structure and the substrate comprise a first semiconductor material; forming a first liner structure and a second liner structure at least extending along sidewalls of the first fin structure and sidewalls of the second fin structure, respectively; replacing an upper portion of the second fin structure with a second semiconductor material, while leaving the first fin structure substantially intact; and exposing a top surface and upper sidewalls of the first fin structure, and a top surface and upper sidewalls of the second fin structure.

In some embodiments, the exposed upper sidewalls of the first fin structure are formed of the first semiconductor material, while the exposed upper sidewalls of the second fin structure are formed of the second semiconductor material.

In some embodiments, the exposed upper sidewalls of the first fin structure have a first height and the exposed upper sidewalls of the second fin structure have a second height, the second height being greater than the first height.

In some embodiments, the method further includes forming a gate dielectric over the first fin structure and the second fin structure, respectively; and forming a gate metal over the first fin structure and the second fin structure, respectively.

In some embodiments, the first fin structure operatively serves as a conduction channel of an n-type field-effect-transistor, and the second fin structure operatively serves as a conduction channel of a p-type field-effect-transistor.

In some embodiments, the first semiconductor material is silicon, and the second semiconductor material is silicon germanium.

In some embodiments, the first liner structure further overlays a first mask layer defining the first fin structure, and the second liner structure further overlays a second mask layer defining the second fin structure.

In some embodiments, the step of replacing an upper portion of the second fin structure with a second semiconductor material, while leaving the first fin structure substantially intact further includes: overlaying the first fin structure and second fin structure with an isolation structure; covering the first region; removing a portion of the isolation structure in the second region, the second mask layer, and the upper portion of the second fin structure, while leaving the first region substantially intact; and epitaxially growing, from a lower portion of the second fin structure, the second semiconductor material as the replacement upper portion of the second fin structure. Prior to the step of exposing a top surface and upper sidewalls of the first fin structure, and a top surface and upper sidewalls of the second fin structure, further includes polishing the isolation material, the first liner structure, the second liner structure, and the replacement upper portion of the second fin structure until the first mask layer is exposed.

Yet another aspect of the present disclosure is directed to a method for fabricating semiconductor devices. The method includes forming a fin structure protruding from a substrate, wherein the fin structure and the substrate comprise a first semiconductor material; forming a liner structure extending along sidewalls of the fin structure and overlaying a top surface of the fin structure; removing a portion of the liner structure overlaying the top surface and then an upper portion of the fin structure; epitaxially growing, from a lower portion of the fin structure, a second semiconductor material as a replacement upper portion of the fin structure, the second semiconductor material being different from the first semiconductor material; exposing upper sidewalls of the fin structure; and forming a gate structure straddling the fin structure.

In some embodiments, the first semiconductor material is silicon, and the second semiconductor material is silicon germanium.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flow chart of an example method for making a non-planar transistor structure, in accordance with some embodiments.

FIGS. 2A, 2B, 2C, 2D, 2E, 2F, 2G, 2H, 2I, and 2J illustrate cross-sectional views of an example non-planar transistor structure during various fabrication stages, made by the method of FIG. 1, in accordance with some embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

The present disclosure provides various embodiments of methods for forming a semiconductor device including at least a first fin structure formed of a first semiconductor material, which may operatively serve as the conduction channel of an n-type field-effect-transistor, and a second fin structure formed of a second, different semiconductor material, which may operatively serve as the conduction channel of a p-type field-effect-transistor. For example, a first fin structure and a second fin structure may be initially defined in a first region and a second region of a substrate, respectively. As defined (e.g., through patterning the substrate), the first and second fin structures may be formed of the same first semiconductor material as the substrate. Next, while leaving the first region substantially intact, an upper portion of the second fin structure may be replaced with a different second semiconductor material. In various embodiments, the first semiconductor material may include silicon, and the second semiconductor material may include silicon germanium. As such, the first fin structure can operatively serve as the conduction channel of an n-type field-effect-transistor (higher electron mobility), and the second fin structure can operatively serve as the conduction channel of a p-type field-effect-transistor (higher hole mobility).

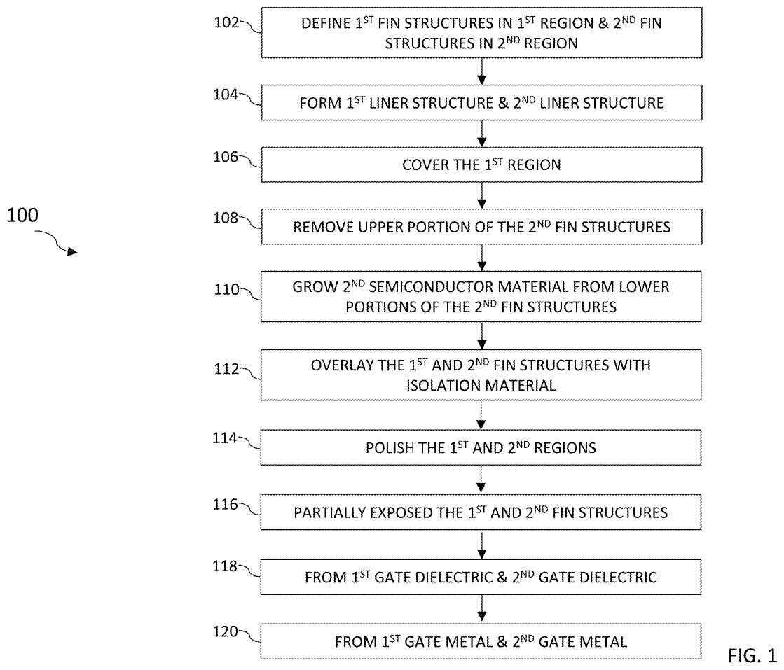

FIG. 1 illustrates a flowchart of a method 100 to form a semiconductor device including both a first field-effect-transistor (FET) structure and a second FET structure, according to one or more embodiments of the present disclosure. For example, at least some of the operations (or steps) of the method 100 can be used to form one or more n-type FinFET structures and one or more p-type FinFET structures. However, it should be understood that the first transistor structure and second transistor structure, formed by the method 100, may be configured as any of various other structures such as, for example, a gate-all-around (GAA) transistor structure, a channel-all-around (CAA) transistor structure, a vertical transistor structure, or the like, while remaining within the scope of the present disclosure. In the following discussion, the FinFET structure is referred to as a transistor solely for the sake of brevity. It is noted that the method 100 is merely an example, and is not intended to limit the present disclosure. Accordingly, it is understood that additional operations may be provided before, during, and after the method 100 of FIG. 1, and that some other operations may only be briefly described herein.

In brief overview, the method 100 starts with operation 102 in which a number of first fin structures and a number of second fin structures are defined in a first region and a second region of a substrate, respectively. The first fin structures and second fin structures are formed of the same first semiconductor material as the substrate. The method 100 proceeds to operation 104 in which a first liner structure and a second liner structure are formed over the first fin structures and second fin structures, respectively. The method 100 proceeds to operation 106 in which the first region is covered for processing the second region. The method 100 proceeds to operation 108 in which respective upper portions of the second fin structures are removed. The method 100 proceeds to operation 110 in which a second, different semiconductor material is epitaxially grown from a respective lower portion of each of the second fin structures. The method 100 proceeds to operation 112 in which the first fin structures and second fin structures are overlaid by an isolation material. The method 100 proceeds to operation 114 in which a polishing process is performed on both the first and second regions to expose a top surface of each of the newly formed second fin structures. The method 100 proceeds to operation 116 in which the first fin structures and the second fin structures are partially exposed, respectively. The method 100 proceeds to operation 118 in which a first gate dielectric and a second gate dielectric are formed over the first fin structures and the second fin structures, respectively. The method 100 proceeds to operation 120 in which a first gate metal and a second gate metal are formed over the first fin structures and the second fin structures, respectively.

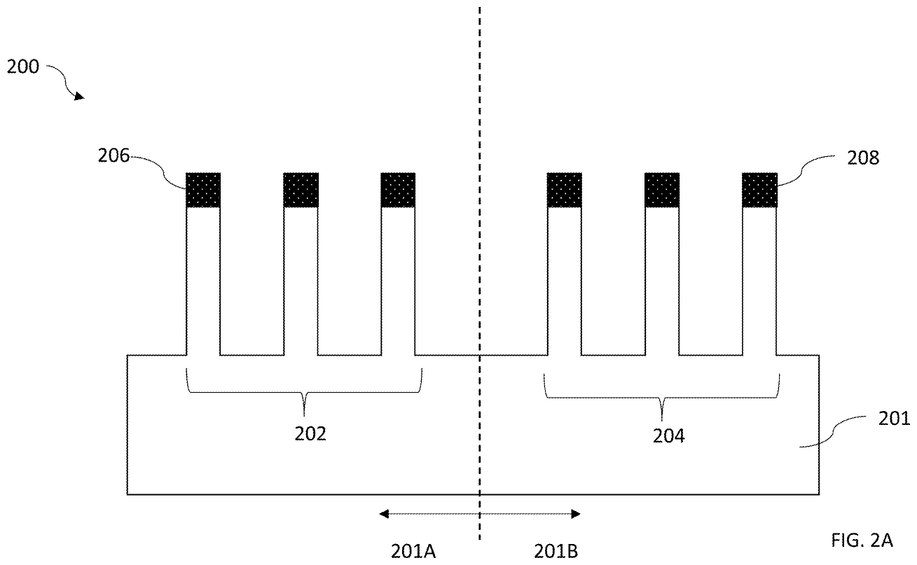

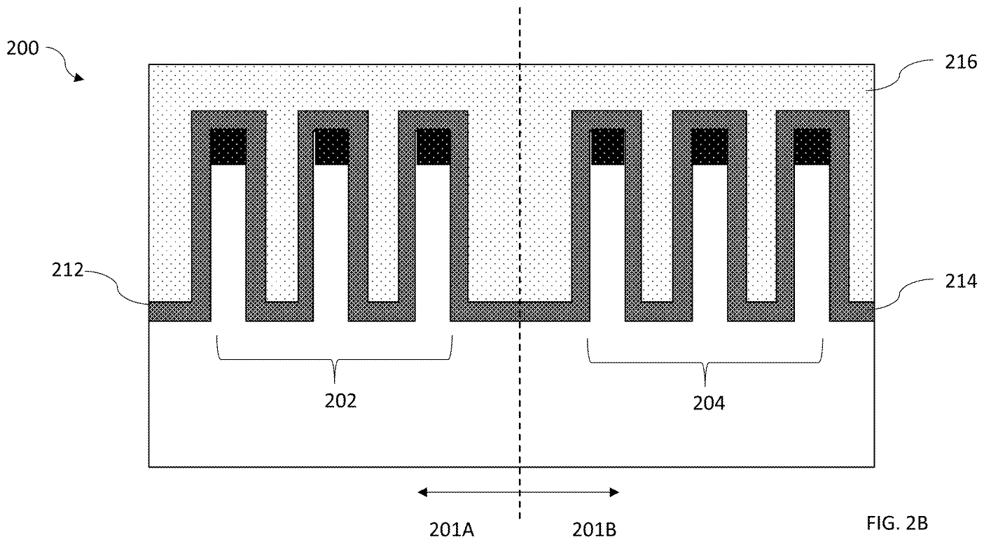

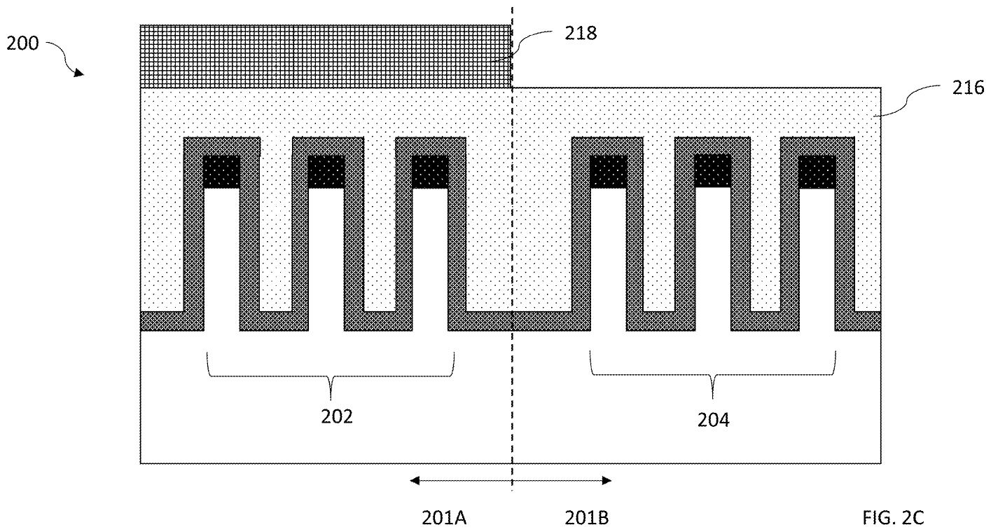

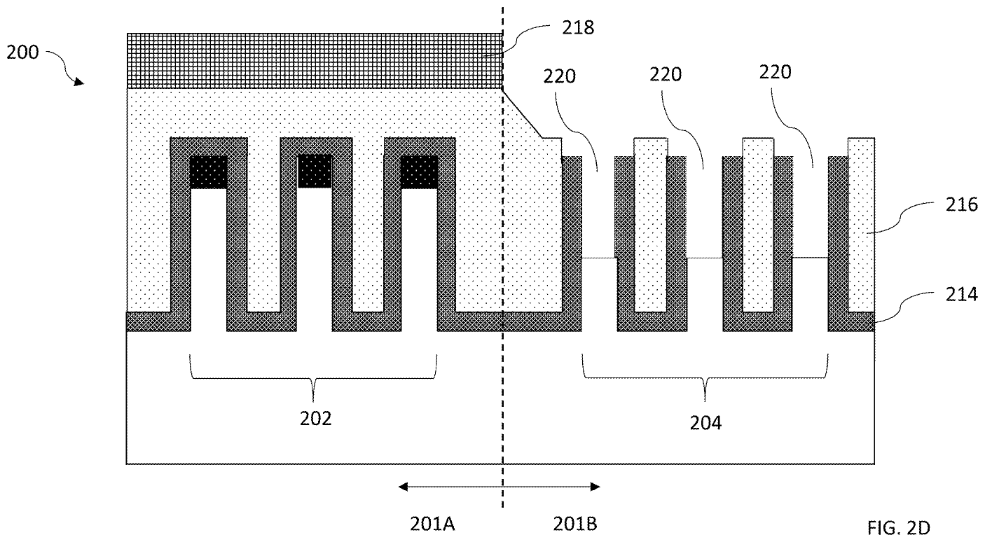

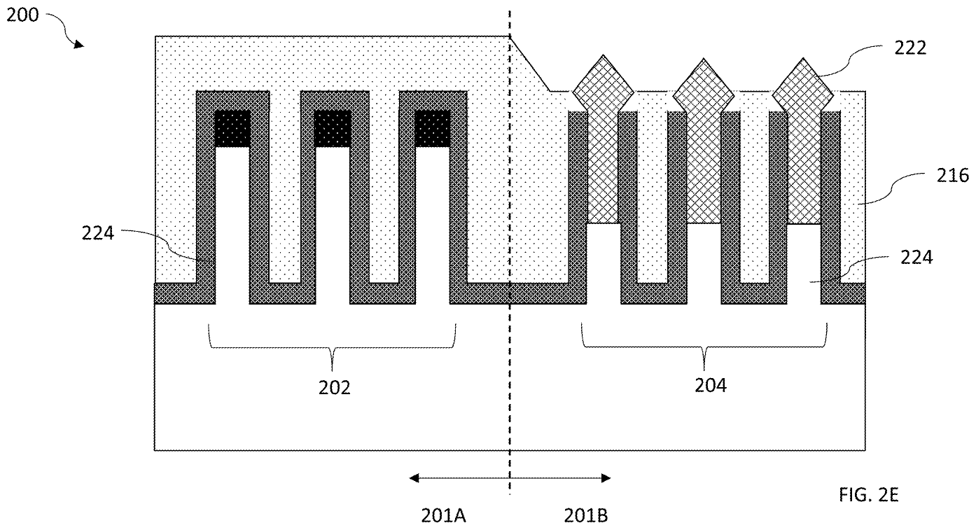

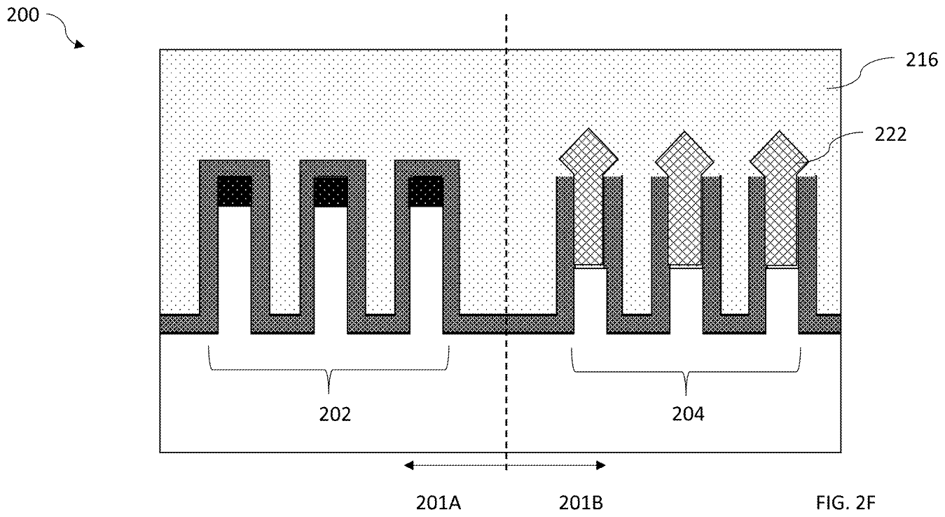

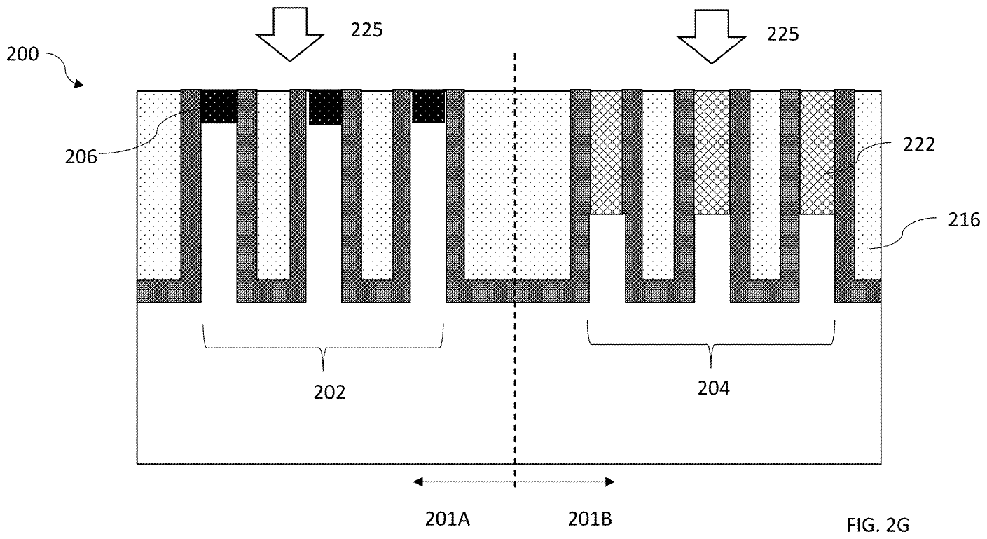

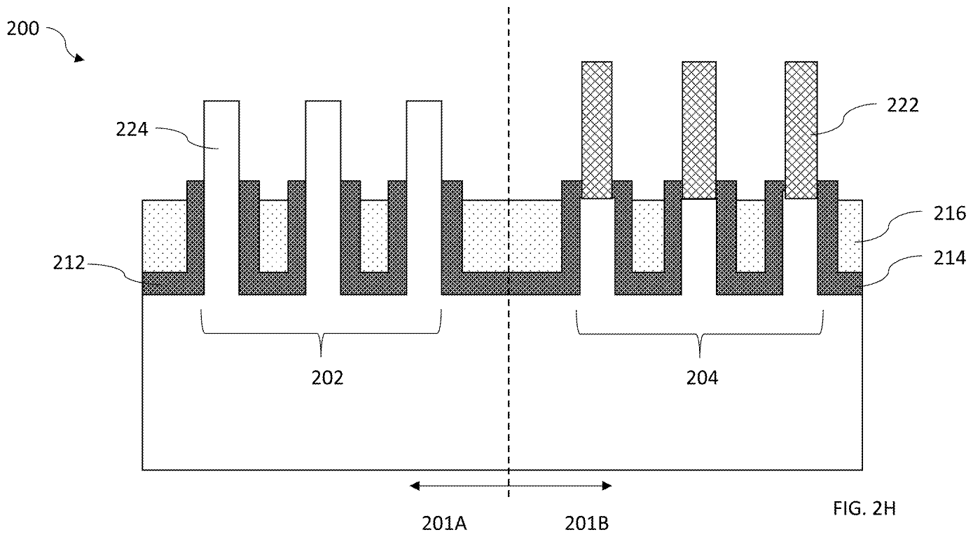

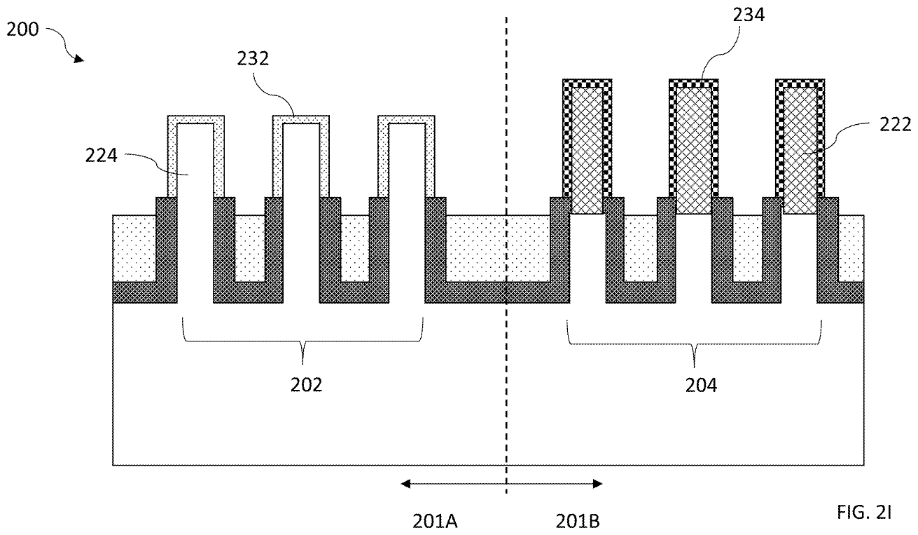

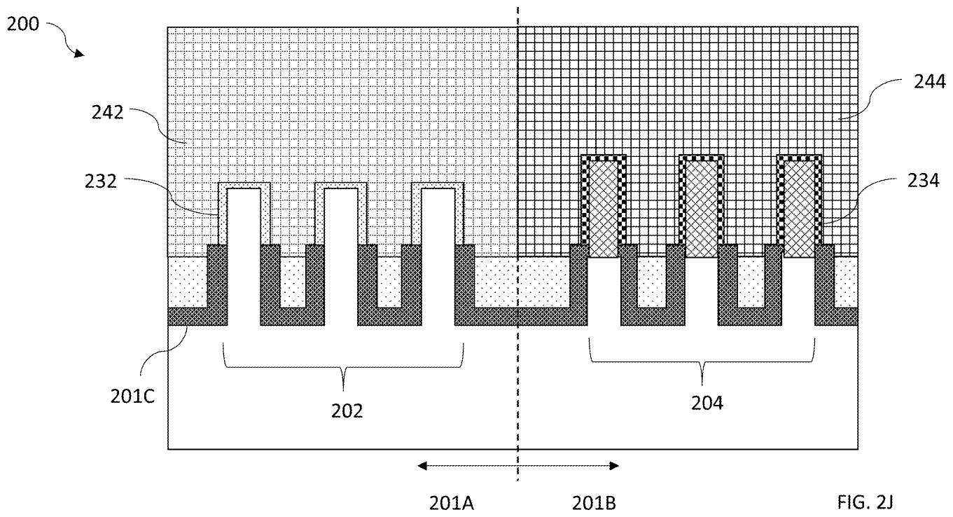

In some embodiments, operations of the method 100 may be associated with cross-sectional views of an example semiconductor device 200 (e.g., including a first transistor configured in n-type and a second transistor configured in p-type) at various fabrication stages as shown in FIGS. 2A-2J, respectively, which will be discussed in further detail below. It should be understood that the semiconductor device 200 shown in FIGS. 2A-2J may not include completed FinFET structures for the purposes of brevity. For example, the following figures of the semiconductor device 200 may not illustrate or include source/drain structures coupled to opposite sides of each of the channels (fin structures).

Corresponding to operation 102 of FIG. 1, FIG. 2A is a cross-sectional view of the semiconductor device 200 in which first fin structures 202 and second fin structures 204 are formed in a first region 201A and a second region 201B of a substrate 201, respectively, at one of the various stages of fabrication, in accordance with various embodiments of the present disclosure. The cross-sectional view of FIG. 2A may be cut in a direction perpendicular to the lengthwise direction of one or more channels of the semiconductor device 200 (e.g., the lengthwise direction of an active/dummy gate structure of the semiconductor device 200).

The substrate 201 may be a semiconductor substrate, such as a bulk semiconductor, a semiconductor-on-insulator (SOI) substrate, or the like, which may be doped (e.g., with a p-type or an n-type dopant) or undoped. The substrate 201 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 201 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; or combinations thereof.

In some embodiments, the substrate 201 includes at least a first region 201A and a second region 201B, where the first region 201A and second region 201B may be configured to form one or more transistors with a first conductive type (e.g., n-type) and one or more transistors with a second conductive type (e.g., p-type), respectively. The first and second fin structures 202 and 204 can be formed by patterning the substrate 201 using, for example, photolithography and etching techniques. As such, the first fin structures 202 and the second fin structures 204 are formed of the same first semiconductor material as the substrate 201 (e.g., silicon). For example, a first mask layer 206 and a second mask layer 208 are formed over the first region 201A and second region 201B, respectively. Each of the mask layers 206 and 208 includes a pad oxide layer and an overlying pad nitride layer. The pad oxide layer may be a thin film comprising silicon oxide formed, for example, using a thermal oxidation process. The pad oxide layer may act as an adhesion layer between the substrate 201 and the overlying pad nitride layer. In some embodiments, the pad nitride layer is formed of silicon nitride, silicon oxynitride, silicon carbonitride, the like, or combinations thereof. The pad nitride layer may be formed using low-pressure chemical vapor deposition (LPCVD) or plasma enhanced chemical vapor deposition (PECVD), for example.

The first and second mask layers, 206 and 208, may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layers and pad nitride layers to form the patterned mask layer 206 and patterned mask layer 208 in the first region 201A and second region 201B, respectively, as illustrated in FIG. 2A.

The patterned mask layers, 206 and 208, are subsequently used to pattern exposed portions of the substrate 201 to define the first fin structures 202 in the first region 201A and the second fin structures 204 in the second region 201B, respectively, as illustrated in FIG. 2A. Further, a trench is interposed between any adjacent ones of the fin structures. In some embodiments, the first and second fin structures, 202 and 204, are formed by etching trenches in the substrate 201 using, for example, reactive ion etch (RIE), neutral beam etch (NBE), the like, or combinations thereof. The etching may be anisotropic. In some embodiments, the trenches between adjacent fin structures may be strips (viewed from the top) parallel to each other, and closely spaced with respect to each other. In some embodiments, the trenches may be continuous and surround the corresponding fin structure(s).

The first and second fin structures, 202 and 204, may be concurrently patterned by any suitable method. For example, the fin structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fin structures.

Corresponding to operation 104 of FIG. 1, FIG. 2B is a cross-sectional view of the semiconductor device 200 in which a first liner structure 212 is formed over each of the first fin structures 202 and a second liner structure 214 is formed over each of the second fin structures 204, respectively, at one of the various stages of fabrication, in accordance with various embodiments of the present disclosure. The cross-sectional view of FIG. 2B may be cut in a direction perpendicular to the lengthwise direction of one or more channels of the semiconductor device 200 (e.g., the lengthwise direction of an active/dummy gate structure of the semiconductor device 200).

Upon defining the first fin structures 202 and the second fin structures 204, the first liner structure 212 is formed over the first fin structures 202 and the second liner structure 214 is formed over the second fin structures 204. For example in FIG. 2B, the first liner structure 212 can extend along sidewalls of each of the first fin structures 202 and overlays a top surface of each of the first fin structures 202 (with the first mask layer 206 interposed therebetween). Similarly, the second liner structure 214 can extend along sidewalls of each of the second fin structures 204 and overlays a top surface of each of the second fin structures 204 (with the second mask layer 208 interposed therebetween). Further, the first liner structure 212 overlays a bottom surface of each of the trenches interposed between the adjacent first fin structures 202, and the second liner structure 214 overlays a bottom surface of each of the trenches interposed between the adjacent second fin structures 204, as illustrated in FIG. 2B. In some embodiments, the first and second liner structures, 212 and 214, may be concurrently deposited over the first region 201A and second region 201B, respectively, through a flowable CVD (FCVD), e.g., a CVD-based material deposition in a remote plasma system and post curing to make it convert to another material, such as silicon oxide. In some other embodiments, the first and second liner structures, 212 and 214, may be a thermal oxide formed through a thermal oxidation on the surfaces of the first fin structures 202, second fin structures 204, substrate 201, although other suitable method may also be used.

Following the formation of the first liner structure 212 and second liner structure 214, an isolation/insulation material 216 is formed between adjacent one of the fin structures, i.e., filling the trenches between the adjacent first fin structures 202 and the trenches between the adjacent second fin structures 204. The insulation material 216 can electrically isolate neighboring fins from each other. The insulation material may be an oxide, such as silicon oxide, a nitride, the like, or combinations thereof, and may be formed by a high density plasma chemical vapor deposition (HDP-CVD), a flowable CVD (FCVD), the like, or combinations thereof. Other insulation materials and/or other formation processes may be used. An anneal process may be performed once the insulation material is formed. A planarization process, such as a chemical mechanical polish (CMP), may remove any excess insulation material.

Corresponding to operation 106 of FIG. 1, FIG. 2C is a cross-sectional view of the semiconductor device 200 in which the first region 201A is covered by a patterned mask layer 218 for processing the second region 201B, at one of the various stages of fabrication, in accordance with various embodiments of the present disclosure. The cross-sectional view of FIG. 2C may be cut in a direction perpendicular to the lengthwise direction of one or more channels of the semiconductor device 200 (e.g., the lengthwise direction of an active/dummy gate structure of the semiconductor device 200).

Corresponding to operation 108 of FIG. 1, FIG. 2D is a cross-sectional view of the semiconductor device 200 in which respective upper portions of the second fin structures 204 are removed, with the first region 201A remaining covered, at one of the various stages of fabrication, in accordance with various embodiments of the present disclosure. The cross-sectional view of FIG. 2D may be cut in a direction perpendicular to the lengthwise direction of one or more channels of the semiconductor device 200 (e.g., the lengthwise direction of an active/dummy gate structure of the semiconductor device 200).

With the patterned mask layer 218 covering the first region 201A, a portion of the insulation material 216 in the second region 201B is removed, followed by removing respective upper portions of the second fin structures 204. Specifically, the portion of the insulation material 216 is recessed through a dry or wet etching process using dilute hydrofluoric (DHF) acid. In some embodiments, an etching selectivity may be present between the insulation material 216 and the second liner structure 214, which causes the second liner structure 214 to remain approximately intact and be exposed. Next, another etching process may be performed to break through the second liner structure 214 then remove the second mask layer 208, exposing the top surface of each of the second fin structures 204. Next, yet another etching process, with a substantially high selectivity between the material of the second fin structures 204 and the material of the second liner structure 214, may be performed to remove the upper portions of the second fin structure 204. Accordingly, a lower portion of each of the second fin structures 204 is recessed from the second liner structure 214, forming a recess 220 above each of the remaining lower portions of the second fin structures 204, as shown in FIG. 2D.

Corresponding to operation 110 of FIG. 1, FIG. 2E is a cross-sectional view of the semiconductor device 200 in which a second semiconductor material 222 is epitaxially grown through each of the recesses 220 (FIG. 2D), at one of the various stages of fabrication, in accordance with various embodiments of the present disclosure. The cross-sectional view of FIG. 2E may be cut in a direction perpendicular to the lengthwise direction of one or more channels of the semiconductor device 200 (e.g., the lengthwise direction of an active/dummy gate structure of the semiconductor device 200).

In various embodiments of the present disclosure, the second semiconductor material is different from the first semiconductor material of the first fin structures 202 and the remaining lower portions of the second fin structures 204, hereinafter “first semiconductor material 224.” Further, compared to the first semiconductor material 224 (e.g., silicon (Si)) which is characterized with a higher electron mobility, the second semiconductor material 222 may be characterized with a higher hole mobility, e.g., silicon germanium (SixGel-x, where x can be between 0 and 1) or even pure germanium (Ge). The second semiconductor material 222 can be epitaxially grown from the remaining lower portion of each second fin structure 204 through suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof. In the example of FIG. 2E, the second semiconductor material 222 may upwardly extend above the second liner structures 214.

Corresponding to operation 112 of FIG. 1, FIG. 2F is a cross-sectional view of the semiconductor device 200 in which the insulation material 216 is again deposited to overlay the newly formed second fin structures 204, at one of the various stages of fabrication, in accordance with various embodiments of the present disclosure. The cross-sectional view of FIG. 2F may be cut in a direction perpendicular to the lengthwise direction of one or more channels of the semiconductor device 200 (e.g., the lengthwise direction of an active/dummy gate structure of the semiconductor device 200).

Corresponding to operation 114 of FIG. 1, FIG. 2G is a cross-sectional view of the semiconductor device 200 in which a polishing/planarization process 225 is performed on both of the first region 201A and second region 201B, at one of the various stages of fabrication, in accordance with various embodiments of the present disclosure. The cross-sectional view of FIG. 2G may be cut in a direction perpendicular to the lengthwise direction of one or more channels of the semiconductor device 200 (e.g., the lengthwise direction of an active/dummy gate structure of the semiconductor device 200).

The polishing process 225 such as, for example, a chemical mechanical polish (CMP) process, may remove any excess insulation material 216 until the first mask layer 206 is exposed, thereby causing at least the first mask layer 206 and the newly formed second fin structures 204 to be coplanar with each other. For example in the illustrated embodiment of FIG. 2G, at least a top surface of the first mask layer 206 and a top surface of the newly formed second fin structures 204 (e.g., a polished top surface of the second semiconductor material 222) are aligned along a horizontal plane. Alternatively stated, the top surface of the first fin structures 202 (which is currently overlaid by the first mask layer 206) may be vertically lower than the top surface of the second fin structures 204.

Corresponding to operation 116 of FIG. 1, FIG. 2H is a cross-sectional view of the semiconductor device 200 in which an upper portion of each of the first fin structures 202 and an upper portion of each of the second fin structures 204 are revealed, at one of the various stages of fabrication, in accordance with various embodiments of the present disclosure. The cross-sectional view of FIG. 2H may be cut in a direction perpendicular to the lengthwise direction of one or more channels of the semiconductor device 200 (e.g., the lengthwise direction of an active/dummy gate structure of the semiconductor device 200).

Following the polishing process 225 (FIG. 2G), the first mask layer 206, an upper portion of the insulation material 216, an upper portion of the first liner structure 212, and an upper portion of the second liner structure 214 can be respectively or concurrently removed. For example, a dry or wet etching process using dilute hydrofluoric (DHF) acid may be performed to remove such features. As a result, upper sidewalls and the top surface of each of the first fin structures 202 (or the first semiconductor material 224), and upper sidewalls and the top surface of each of the second fin structures 204 (or the second semiconductor material 222) can be exposed, as shown in FIG. 2H. Further, in some embodiments, the second liner structure 214 may have a remaining lower portion with a top surface that is vertically higher than an interface between the first semiconductor material 224 and the second semiconductor material 222. As such, in the second region 201B, only the second semiconductor material 222 is exposed.

Corresponding to operation 118 of FIG. 1, FIG. 2I is a cross-sectional view of the semiconductor device 200 in which a first gate dielectric 232 is formed over each of the first fin structures 202 and a second gate dielectric 234 is formed over each of the second fin structures 204, at one of the various stages of fabrication, in accordance with various embodiments of the present disclosure. The cross-sectional view of FIG. 2I may be cut in a direction perpendicular to the lengthwise direction of one or more channels of the semiconductor device 200 (e.g., the lengthwise direction of an active/dummy gate structure of the semiconductor device 200).

As shown, the first gate dielectric 232 can straddle the exposed top surface and upper sidewalls of each of the first fins structures 202; and the second gate dielectric 234 can straddle the exposed top surface and upper sidewalls of each of the second fins structures 204. In some embodiments, the first gate dielectric 232 and second gate dielectric 234 may be concurrently or respectively formed through molecular beam deposition (MBD), atomic layer deposition (ALD), PECVD, and the like. The first gate dielectric 232 and second gate dielectric 234 may each have a k value greater than about 7.0, and may include a metal oxide or a silicate of Hf, Al, Zr, La, Mg, Ba, Ti, Pb, or combinations thereof. The first gate dielectric 232 and second gate dielectric 234 may be modified (e.g., doped) through an interface dipole engineering so as to adjust the flat band voltage of a corresponding active (e.g., metal) gate structure. Different flat band voltages can correspond to different threshold voltages.

Corresponding to operation 120 of FIG. 1, FIG. 2J is a cross-sectional view of the semiconductor device 200 in which a first gate metal 242 is formed over each of the first fin structures 202 and a second gate metal 244 is formed over each of the second fin structures 204, at one of the various stages of fabrication, in accordance with various embodiments of the present disclosure. The cross-sectional view of FIG. 2J may be cut in a direction perpendicular to the lengthwise direction of one or more channels of the semiconductor device 200 (e.g., the lengthwise direction of an active/dummy gate structure of the semiconductor device 200).

As shown, the first gate metal 242 can further straddle the first fin structures 202 with the first gate dielectric 232 interposed therebetween; and the second gate metal 244 can further straddle the second fin structures 204 with the second gate dielectric 234 interposed therebetween. The first gate metal 242 and second gate metal 244 may each include a p-type work function layer, an n-type work function layer, multi-layers thereof, or combinations thereof. Example p-type work function metals that may include TiN, TaN, Ru, Mo, Al, WN, ZrSi₂, MoSi₂, TaSi₂, NiSi₂, WN, other suitable p-type work function materials, or combinations thereof. Example n-type work function metals that may include Ti, Ag, TaAl, TaAlC, TiAlN, TaC, TaCN, TaSiN, Mn, Zr, other suitable n-type work function materials, or combinations thereof.

The first gate dielectric 232 and the first gate metal 242 may sometimes be collectively referred to as a first active (metal) gate structure; and the second gate dielectric 234 and the second gate metal 244 may sometimes be collectively referred to as a second active (metal) gate structure. In some embodiments, one or more of the first fin structures 202 may operatively serve as the channel of an n-type transistor; and one or more of the second fin structures 204 may operatively serve as the channel of a p-type transistor. Accordingly, the first metal gate structure (232 and 242) may operatively serve as a gate of the n-type transistor, and the second metal gate structure (234 and 244) may operatively serve as a gate of the p-type transistor. Due to the nature of how the respective channels of the n-type transistor and p-type transistor are formed, the channel of the n-type transistor may have a height shorter than a height of the channel of the p-type transistor. Stated another way, starting from a major surface 201C of the substrate, the first fin structures 202 each outwardly extend with a first distance and the second fin structures 204 each outwardly extend with a second distance, where the second distance is greater than the first distance.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a substrate comprising a first region and a second region;
a first fin structure disposed in the first region and comprising a first semiconductor material; and
a second fin structure disposed in the second region and comprising a second semiconductor material different from the first semiconductor material,
wherein the first fin structure has a first height and the second fin structure has a second height, the second height being greater than the first height.

2. The semiconductor device of claim 1, wherein the first fin structure protrudes from a major surface of the substrate and comprises only the first semiconductor material.

3. The semiconductor device of claim 2, wherein the second fin structure protrudes from the major surface of the substrate and comprises both the first semiconductor material and the second semiconductor material.

4. The semiconductor device of claim 3, wherein the second fin structure has a lower portion formed of the first semiconductor material, and an upper portion formed of the second semiconductor material.

5. The semiconductor device of claim 1, further comprising:
a first liner structure extending sidewalls of a lower portion of the first fin structure; and
a second liner structure extending sidewalls of a lower portion of the second fin structure.

6. The semiconductor device of claim 5, wherein an interface between an upper portion and the lower portion of the second fin structure is vertically located slightly below a top surface of the second liner structure.

7. The semiconductor device of claim 6, wherein the lower portion is formed of the first semiconductor material, while the upper portion is formed of the second semiconductor material.

8. The semiconductor device of claim 1, wherein the first fin structure operatively serves as a conduction channel of an n-type field-effect-transistor, and the second fin structure operatively serves as a conduction channel of a p-type field-effect-transistor.

9. The semiconductor device of claim 1, wherein the first semiconductor material is silicon, and the second semiconductor material is silicon germanium.

10. A method for fabricating semiconductor devices, comprising:
forming a first fin structure and a second fin structure in a first region and a second region of a substrate, respectively, wherein the first and second fin structure and the substrate comprise a first semiconductor material;
forming a first liner structure and a second liner structure at least extending along sidewalls of the first fin structure and sidewalls of the second fin structure, respectively;
replacing an upper portion of the second fin structure with a second semiconductor material, while leaving the first fin structure substantially intact; and
exposing a top surface and upper sidewalls of the first fin structure, and a top surface and upper sidewalls of the second fin structure.

11. The method of claim 10, wherein the exposed upper sidewalls of the first fin structure are formed of the first semiconductor material, while the exposed upper sidewalls of the second fin structure are formed of the second semiconductor material.

12. The method of claim 10, wherein the exposed upper sidewalls of the first fin structure have a first height and the exposed upper sidewalls of the second fin structure have a second height, the second height being greater than the first height.

13. The method of claim 10, further comprising:
forming a gate dielectric over the first fin structure and the second fin structure, respectively; and
forming a gate metal over the first fin structure and the second fin structure, respectively.

14. The method of claim 10, wherein the first fin structure operatively serves as a conduction channel of an n-type field-effect-transistor, and the second fin structure operatively serves as a conduction channel of a p-type field-effect-transistor.

15. The method of claim 10, wherein the first semiconductor material is silicon, and the second semiconductor material is silicon germanium.

16. The method of claim 10, wherein the first liner structure further overlays a first mask layer defining the first fin structure, and the second liner structure further overlays a second mask layer defining the second fin structure.

17. The method of claim 16, wherein the step of replacing an upper portion of the second fin structure with a second semiconductor material, while leaving the first fin structure substantially intact further comprises:
overlaying the first fin structure and second fin structure with an isolation structure;
covering the first region;
removing a portion of the isolation structure in the second region, the second mask layer, and the upper portion of the second fin structure, while leaving the first region substantially intact; and
epitaxially growing, from a lower portion of the second fin structure, the second semiconductor material as the replacement upper portion of the second fin structure.

18. The method of claim 17, prior to the step of exposing a top surface and upper sidewalls of the first fin structure, and a top surface and upper sidewalls of the second fin structure, further comprising:
polishing the isolation material, the first liner structure, the second liner structure, and the replacement upper portion of the second fin structure until the first mask layer is exposed.

19. A method for fabricating semiconductor devices, comprising:
forming a fin structure protruding from a substrate, wherein the fin structure and the substrate comprise a first semiconductor material;
forming a liner structure extending along sidewalls of the fin structure and overlaying a top surface of the fin structure;
removing a portion of the liner structure overlaying the top surface and then an upper portion of the fin structure;
epitaxially growing, from a lower portion of the fin structure, a second semiconductor material as a replacement upper portion of the fin structure, the second semiconductor material being different from the first semiconductor material;
exposing upper sidewalls of the fin structure; and
forming a gate structure straddling the fin structure.

20. The method of claim 19, wherein the first semiconductor material is silicon, and the second semiconductor material is silicon germanium.
